(19) United States
(12) Patent Application Publication
(10) Pub. No.: US 2024/0224807 A1
(43) Pub. Date: Jul. 4, 2024

(54) PIEZOELECTRIC MATERIAL COMPOSITION, PIEZOELECTRIC DEVICE, METHOD OF MANUFACTURING THE SAME, AND APPARATUS INCLUDING THE PIEZOELECTRIC DEVICE

(71) Applicant: LG DISPLAY CO., LTD., SEOUL (KR)

(72) Inventors: Uihyeon JEONG, Gyeonggi-do (KR); YongWoo LEE, Gyeonggi-do (KR); JounHo LEE, Gyeonggi-do (KR); Sooyoun KIM, Gyeonggi-do (KR); HwaYoul LEE, Gyeonggi-do (KR)

(73) Assignee: LG DISPLAY CO., LTD., SEOUL (KR)

(21) Appl. No.: 18/387,095

(22) Filed: Nov. 6, 2023

(30) Foreign Application Priority Data
Dec. 30, 2022 (KR) 10-2022-0191182

(51) Int. Cl. H10N 30/853; H10N 30/053; H10N 30/067; H10N 30/20; H10N 30/50

(52) U.S. Cl. CPC H10N 30/853; H10N 30/053; H10N 30/067; H10N 30/20; H10N 30/50

(57) ABSTRACT

A piezoelectric material composition includes a first material, and a second material in the first material, wherein the piezoelectric material composition represented by (Equation 1) 0.96(NaₐK₁₋ₐ)(Nb_{b}(Sb_{1-b}))O₃-(0.04-x)MZrO₃-x(Bi_{c}Ag_{1-c})ZrO₃+d mol % E, where 1, M denotes strontium (Sr), barium (Ba), or calcium (Ca), E denotes the second material, 0.40≤a≤0.60, 0.90≤b≤0.98, 0.30≤c≤0.70, 0.00<x≤0.04, and 0.00<d≤5.00) or (Equation 2) 0.96(NaₐK₁₋ₐ)(Nb_{b}(T_{1-b}))O₃-(0.04-x)M_{A}M_{B}O₃-x(Bi_{c}Ag_{1-c})M_{B}O₃+d mol % E, where T denotes antimony (Sb), tantalum (Ta), or vanadium (V), M_{A} denotes Sr, Ba, or Ca, M_{B} denotes zirconium (Zr), hafnium (Hf), titanium (Ti), or tin (Sn), E denotes the second material, 0.40≤a≤0.60, 0.90≤b≤1.00, 0.30≤c≤0.70, 0.00≤x≤0.04, and 0.00<d≤5.00).

### CROSS-REFERENCE TO RELATED APPLICATION

This application claims the priority of Korean Patent Application No. 10-2022-0191182 filed on Dec. 30, 2022, which is hereby incorporated by reference in its entirety.

### BACKGROUND

### Field of the Disclosure

The present disclosure relates to a piezoelectric material composition, a piezoelectric device, a method of manufacturing the same, and an apparatus including the piezoelectric device.

### Description of the Background

Piezoelectric materials are being widely used as materials of parts such as ultrasound vibrators, electromechanical transducers, and actuators used in the extensive field of ultrasound devices, video devices, sound devices, communication devices, and sensors.

Pb(Zr, Ti)O₃ (PZT)-based materials have a high piezoelectric characteristic, and thus, are used as a piezoelectric part material. However, lead (Pb) is a material having strong toxicity and has high volatility in a sintering process, and due to this, causes serious environmental pollution.

Therefore, because a PZT piezoelectric material occupying the most of piezoelectric materials causes an environmental pollution problem, it is required to develop a Pb-free piezoelectric material, and thus, a high piezoelectric characteristic is needed.

### SUMMARY

Accordingly, the present disclosure is directed to a piezoelectric material composition, a piezoelectric device, a method of manufacturing the same, and an apparatus including the piezoelectric device that substantially obviates one or more of problems due to limitations and disadvantages described above.

More specifically, the present disclosure is to provide a piezoelectric device which may not include lead and may have a high piezoelectric characteristic.

The present disclosure is also to provide a piezoelectric device in which a piezoelectric material composition may include a rear-earth material, and thus, an aesthetic effect may be enhanced.

The present disclosure is also to provide a method of manufacturing a piezoelectric material device, which may orient grains of a piezoelectric material by using a template to provide a piezoelectric material composition having a high piezoelectric characteristic, thereby enhancing a piezoelectric characteristic.

The present disclosure is also to provide an apparatus including a piezoelectric device, which may have a high piezoelectric characteristic and may enhance an aesthetic effect.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings. The present disclosure is not limited to the aforesaid, but other features not described herein will be clearly understood by those skilled in the art from descriptions below.

To achieve these and other advantages and in accordance with the present disclosure, as embodied and broadly described, a piezoelectric material composition includes a first material, and a second material in the first material. The piezoelectric material composition is represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M is strontium (Sr), barium (Ba), or calcium (Ca), E is the second material, 0.40≤a≤0.60, 0.90≤b≤0.98, 0.30≤c≤0.70, 0.00≤x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T is antimony (Sb), tantalum (Ta), or vanadium (V), M_{A} is Sr, Ba, or Ca, M_{B} denotes zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00)

In another aspect of the present disclosure, a piezoelectric device comprises a piezoelectric device layer including a piezoelectric material composition, a first electrode layer at a first surface of the piezoelectric device layer, and a second electrode layer at a second surface, differing from the first surface, of the piezoelectric device layer. The piezoelectric material composition comprises a first material, and a second material in the first material, and is represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T is antimony (Sb), tantalum (Ta), or vanadium (V), M_{A} is Sr, Ba, or Ca, M_{B} is zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00.

In another aspect of the present disclosure, a method of manufacturing a piezoelectric device is provided, the method comprises forming a piezoelectric device layer including a piezoelectric material composition, forming a first electrode layer at a first surface of the piezoelectric device layer, and forming a second electrode layer at a second surface of the piezoelectric device layer different from the first surface. The piezoelectric material composition comprises a first material, and a second material in the first material, and is represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T is antimony (Sb), tantalum (Ta), or vanadium (V), M_{A} is Sr, Ba, or Ca, M_{B} is zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00)

In another aspect of the present disclosure, an apparatus comprises a vibration member, and a vibration apparatus configured to vibrate the vibration member, wherein the vibration apparatus comprises one or more piezoelectric devices. The piezoelectric device comprises a piezoelectric device layer including a piezoelectric material composition, a first electrode layer at a first surface of the piezoelectric device layer, and a second electrode layer at a second surface of the piezoelectric device layer different from the first surface. The piezoelectric material composition comprises a first material, and a second material in the first material, and is represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T is antimony (Sb), tantalum (Ta), or vanadium (V), M_{A} is Sr, Ba, or Ca, M_{B} denotes zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00).

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

According to an aspect of the present disclosure, since a piezoelectric material composition, a piezoelectric device, and an apparatus do not include lead (Pb) and has a high piezoelectric characteristic, the piezoelectric device and the apparatus may be driven with a low driving voltage, and thus, a piezoelectric characteristic thereof may be enhanced.

According to an aspect of the present disclosure, a piezoelectric device and an apparatus may simultaneously generate a vibration and light through a piezoelectric device layer, thereby enhancing an aesthetic effect.

According to an aspect of the present disclosure, a piezoelectric device layer may be used as a light source and light may be controlled based on a vibration of the piezoelectric device layer, and thus, various user experiences may be provided to a user by using light.

According to an aspect of the present disclosure, grains of a piezoelectric material may be oriented by using a template to provide a piezoelectric device layer having a high piezoelectric characteristic, thereby enhancing a piezoelectric characteristic.

According to an aspect of the present disclosure, because a piezoelectric material composition, a piezoelectric device, and an apparatus do not include Pb, a production restriction material may be reduced and replacement of a harmful material may be implemented, and thus, an environment-friendly piezoelectric material composition may be provided.

It is to be understood that both the foregoing description and the following description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this disclosure, illustrate aspects of the disclosure and together with the description serve to explain principles of the disclosure.

FIG. 1 is a cross-sectional view illustrating a piezoelectric device according to an aspect of the present disclosure.

FIG. 2 illustrates a method of manufacturing a piezoelectric device according to an aspect of the present disclosure.

FIG. 3 illustrates a method of manufacturing a matrix material in a method of manufacturing a piezoelectric device according to an aspect of the present disclosure.

FIG. 4 illustrates a method of manufacturing a seed in a method of manufacturing a piezoelectric device according to an aspect of the present disclosure.

FIG. 5 illustrates a crystal structure of a piezoelectric device layer according to an aspect of the present disclosure.

FIG. 6 illustrates a grain variation of a seed material occurring in a step of preparing the seed of FIG. 4 according to an aspect of the present disclosure.

FIG. 7 illustrates a wavelength range of a seed according to an aspect of the present disclosure.

FIG. 8 illustrates a wavelength range of a seed according to another aspect of the present disclosure.

FIG. 9 illustrates a microstructure of the seed illustrated in FIG. 8 according to another aspect of the present disclosure.

FIG. 10 is a cross-sectional view illustrating a piezoelectric device according to another aspect of the present disclosure.

FIG. 11 is a cross-sectional view illustrating a piezoelectric device according to another aspect of the present disclosure.

FIG. 12 is a perspective view of an apparatus according to an aspect of the present disclosure.

FIG. 13 is a cross-sectional view taken along line I-I′ of FIG. 12 according to an aspect of the present disclosure.

FIG. 14 illustrates a vibration apparatus of FIG. 12 according to an aspect of the present disclosure.

FIG. 15 is a plan view of an apparatus including a piezoelectric device according to an aspect of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now be made in detail to aspects of the present disclosure, examples of which may be illustrated in the accompanying drawings. In the following description, when a detailed description of well-known functions, structures or configurations may unnecessarily obscure aspects of the present disclosure, the detailed description thereof may have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Furthermore, the present disclosure is only defined by scopes of claims.

Shapes (e.g., sizes, lengths, widths, heights, thicknesses, locations, radii, diameters, and areas), ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “make of,” “formed of,” or the like is used with respect to one or more elements, one or more other elements may be added unless a term such as “only” or the like is used. The terms used in the present disclosure are merely used to describe particular aspects, and are not intended to limit the scope of the present disclosure. The terms of a singular form may include plural forms unless the context clearly indicates otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e. g., a level, range, dimension, size, or the like) is construed to include an error or tolerance range even where no explicit description of such an error or tolerance range is provided. An error or tolerance range may be caused by various factors (e. g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, when a structure is described as being positioned “on,” “upon,” “on top of,” “over,” “under,” “above,” “below,” “beneath,” “near,” “close to,” “adjacent to,” “besides,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, or the like), these elements should not be limited by these terms. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of elements.

For the expression that an element (e.g., layer, film, region, component, section, or the like) is “connected,” “coupled,” “adhered,” or the like to another element, the element may not only be directly connected, coupled, adhered, or the like to another element, but also be indirectly connected, coupled, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); or some combination of A, B, and C (e.g., A and B; A and C; or B and C); or all of A, B, and C. Furthermore, an expression “A B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirety coupled to or combined with each other, may be technically associated with each other, and may be variously inter-operated, linked or driven together. The aspects of the present disclosure may be implemented or carried out independently of each other or may be implemented or carried out together in co-dependent or related relationship. In one or more aspects, the components of each apparatus according to various aspects of the present disclosure are operatively coupled and configured.

Unless otherwise defined, the terms (including technical and scientific terms) used herein have the same meaning as commonly understood by one of ordinary skill in the art to which example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

Hereinafter, aspects of various example aspects of the present disclosure will be described in detail with reference to the accompanying drawings. With respect to reference numerals to elements of each of the drawings, although the same elements may be illustrated in other drawings, like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may differ from an actual scale, dimension, size, and thickness, and thus, aspects of the present disclosure are not limited to a scale, dimension, size, and thickness illustrated in the drawings.

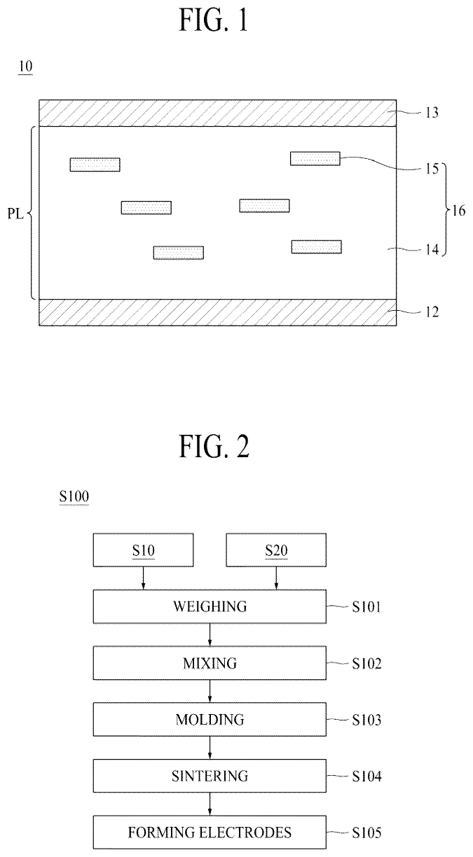

FIG. 1 is a cross-sectional view illustrating a piezoelectric device according to an aspect of the present disclosure.

Referring to FIG. 1, a piezoelectric device 10 according to an aspect of the present disclosure may include a piezoelectric device layer PL, a first electrode layer 12, and a second electrode layer 13. The piezoelectric device layer PL may be provided between the first electrode layer 12 and the second electrode layer 13. The piezoelectric device layer PL may include piezoelectric material composition 16. The piezoelectric material composition 16 may include a first material 14 and a second material 15. For example, each of a plurality of grains including the first material 14 and the second material 15 may be divided by a grain boundary (GB), but aspects of the present disclosure are not limited thereto. According to an aspect of the present disclosure, the piezoelectric material composition 16 may be represented by the following Equation 1.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

In Equation 1, M may be strontium (Sr), barium (Ba), or calcium (Ca), E may be the second material, 0.40≤a≤0.60, 0.90≤b≤0.98, 0.30≤c≤0.70, 0.00<x≤0.04, and 0.00<d≤5.00.

The piezoelectric material composition may further include Fe₂O₃. For example, Fe₂O₃ may be added thereto by 5 mol % or less, but aspects of the present disclosure are not limited thereto.

According to another aspect of the present disclosure, the piezoelectric material composition 16 may be represented by the following Equation 2.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

In Equation 2, T may be antimony (Sb), tantalum (Ta), or vanadium (V), M_{A} may be Sr, Ba, or Ca, M_{B} may be zirconium (Zr), hafnium (Hf), titanium (Ti), or tin (Sn), E may be the second material, 0.40≤a≤0.60, 0.90≤b≤1.00, 0.30≤c≤0.70, 0.00≤x≤0.04, and 0.00<d≤5.00.

The piezoelectric material composition may further include Fe₂O₃. For example, Fe₂O₃ may be added thereto by 5 mol % or less, but aspects of the present disclosure are not limited thereto.

According to another aspect of the present disclosure, the first material 14 may be a matrix material. For example, the first material 14 may include a perovskite compound. The first material 14 may be represented by the following Equation 3.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} \qquad Equation 3$$

In Equation 3, M may be Sr, Ba, or Ca, 0.40≤a≤0.60, 0.90≤b≤0.98, 0.30≤c≤0.70, and 0.00<x≤0.04.

The matrix material may further include Fe₂O₃. For example, Fe₂O₃ may be added thereto by 5 mol % or less, but aspects of the present disclosure are not limited thereto.

According to another aspect of the present disclosure, the first material 14 may be represented by the following Equation 4.

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} \qquad Equation 4$$

In Equation 4, T may be Sb, Ta, or V, M_{A} may be Sr, Ba, or Ca, M_{B} may denote Zr, Hf, Ti, or Sn, 0.40≤a≤0.60, 0.90≤b≤1.00, 0.30≤c≤0.70, and 0.00≤x≤0.04.

The matrix material may further include Fe₂O₃. For example, Fe₂O₃ may be added thereto by 5 mol % or less, but aspects of the present disclosure are not limited thereto.

The first material 14 may be a material except the second material 15 in Equation 1. For example, the first material 14 may include a material (or a piezoelectric material) except a seed which is the second material 15 in Equation 1. For example, Equation 2 may be calculated by excluding the seed in Equation 1.

The first material 14 may include a sintering agent for enhancing sinterability. The sintering agent may be added to the piezoelectric material composition of Equation 2 by 0 mol % to 1 mol %. For example, the sintering agent may be Fe₂O₃, but aspects of the present disclosure are not limited thereto. For example, Fe₂O₃ may be added to the piezoelectric material composition of Equation 2 by 0.5 mol % or less. Accordingly, according to an aspect of the present disclosure, sinterability may be more enhanced.

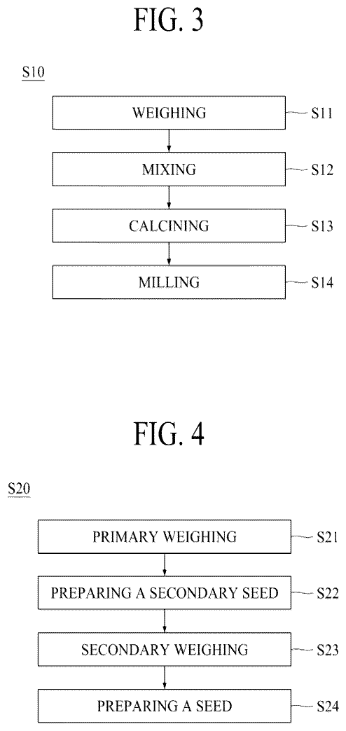

Therefore, according to an aspect of the present disclosure, the second material 15 may be configured to be in the first material 14. For example, the first material 14 may be prepared by a method of preparing a matrix material, which will be described below with reference to FIGS. 2 and 3.

The second material 15 may be formed in the first material 14. The second material 15 may be surrounded by the first material 14. The second material 15 may be disposed at a center portion of the first material 14. For example, the center portion may not numerically and accurately correspond to a center (or middle) in the first material 14 having a certain volume and may be a certain region including a center (or middle) of the first material 14 having a certain volume. For example, the center portion may be a region extending from a center of the first material 14, in the first material 14 having a certain volume. Therefore, in an aspect of the present disclosure, even when the second material 15 is provided at a position deviating from the center (or middle) of the first material 14, this may be within the scope of the present disclosure.

According to an aspect of the present disclosure, the second material 15 may be an emission seed. For example, the second material 15 may be an emission seed where a light emitting material is doped on a seed material having a plate shape.

According to an aspect of the present disclosure, the second material 15 may include one or more of NaNbO₃, BaMgAl₁₀O₁₇, Y₂O₃, Y₂SiO₅, and Zn₂SiO₄, but aspects of the present disclosure are not limited thereto.

For example, templated grain growth (TGG) may be divided into reactive TGG and non-reactive TGG. The matrix material which is the first material 14 may include a (K, Na)NbO₃ (KNN) material, and the matrix material and the second material 15 may include similar materials, thereby manufacturing reactive TGG. For example, the second material 15 may include NaNbO₃. Because the matrix material and the second material 15 include similar materials, reactivity may be enhanced in sintering. Accordingly, a rare-earth material included in the second material 15 may be diffused in the matrix material, thereby enhancing piezoelectric properties.

For example, when the second material includes NaNbO₃, the first material may include a plurality of grains which are oriented in a (001) single orientation. The second material may be disposed in the plurality of grains. The plurality of grains may be grown by reacting from the second material 15. A grain of the first material 14 may be grown based on an orientation of the second material 15. For example, an aspect ratio of the first material 14 may be within a range of 5 to 20 or 10 to 20, but aspects of the present disclosure are not limited thereto. For example, the piezoelectric device layer PL according to an aspect of the present disclosure may include a plurality of first materials 14. For example, the plurality of first materials 14 may have the same crystal orientation. For example, the plurality of first materials 14 may have a (001) crystal orientation. For example, the plurality of first materials 14 may have a crystal structure which is grown in a (001) orientation. For example, the plurality of first materials 14 may be configured to have a size of about 10 μm or more, but aspects of the present disclosure are not limited thereto. For example, when the plurality of first materials 14 have a size of about 10 μm or more, the plurality of first materials 14 may have a plate-shaped layered structure which is favorable to be oriented in a (001) orientation.

As another example, the matrix material which is the first material may include a material having a different composition so that reaction between a KNN material and the second material is not performed, and thus, may be manufactured based on non-reactive TGG. For example, the second material may include BaMgAl₁₀O₁₇, but aspects of the present disclosure are not limited thereto. Because a composition of the second material differs from a composition of the matrix material and a melting point of the second material is high, the second material and the matrix material may not react therebetween in TGG, and crystal growth may be performed. Accordingly, an emission efficiency of the second material 15 may increase, and thus, the second material 15 may have high emission efficiency.

According to an aspect of the present disclosure, the second material 15 may include an inorganic material or an inorganic fluorescent material. For example, the second material 15 may include a rare-earth material. For example, the second material 15 may include one or more rare-earth materials. For example, the second material 15 may include one or more materials of europium (Eu), praseodymium (Pr), lanthanum (La), erbium (Er), and terbium (Tb).

For example, the second material 15 may include ZnS:Mn, ZnS:Al, ZnS:Au, ZnS:Cu, ZnS:Cl, ZnS:AuCuAl, ZnS:CuAl, ZnS:CuCl, ZnS:Tb, ZnS:SmF₃, ZnS:TbF₃, ZnS:TmF₃, SrS:Ce, SrS:Cu, SrS:Eu, CaS:Eu, BaS:Eu, MgS:Eu, CaF₂:Eu²⁺, CaS:Eu²⁺, CaO:Eu²⁺, Ba₂ZnS₃:Mn, ZnAl₂S₄:Mn, ZnGa₂S₄:Mn, Y₂O₂S:Eu, Y₂O₃S:Eu, Y₂SiO₅:Tb, Y₂O₃:Eu, Gd₂O₃:Eu, SrTiO₃:PrMgAl, CaTiO₃:PrMgAl, (Y,Gd)BO₃:Eu, ZnGa₂O₄:Mn, SrGa₂S₄:Eu, Gd₂O₂S:Tb, Y₃AlO₁₂:Tb, Y₂SiO₅:Tb, Zn₂SiO₄:Mn, LaPO₄:Ce, LaPO₄:Tb, BaAli₂O₁₉:Mn, SrAl₂O₄:Eu, ZnGa₂O₄, SrGa₂O₄:Ce, Y₂SiO₅:Ce, Sr₅(PO₄)Cl:Eu, BaMgAl₁₀O₁₇:Eu, BaMgAl₁₄O₂₃:Eu, (SrCaBaMg)₅(PO₄)₃Cl:Eu, Ca₁₀(PO₄)₆FCl:Sb, Ca₁₀(PO₄)₆FCl:MnCaWO₄, (Y,Sr)TaO₄:Nb, Sr₄Al₁₄O₂₅:EuDy, Y₂O₃:Eu³⁺, Y₂O₂S:Eu³⁺, but aspects of the present disclosure are not limited thereto.

According to an aspect of the present disclosure, a small amount of rare-earth material may be doped on a seed material having a plate shape, and thus, the piezoelectric device layer PL or the piezoelectric device 10 may intactly maintain physical properties of the seed material having a plate shape and may have a characteristic where light is emitted in energy excitation.

For example, the second material 15 may be added to the piezoelectric material composition of Equation 1 or 2 by 5 mol % or less. For example, when the second material 15 is an NN seed including NaNbO₃, the second material 15 may function as a template so that the first material 14 grows in a crystal orientation of the second material 15, in a sintering process. For example, the first material 14 may be sintered based on a crystal orientation of the second material 15. Accordingly, crystal orientations of the plurality of first materials 14 may be oriented in the same orientation. As another example, when the second material 15 is an NN seed including BaMgAl₁₀O₁₇, a composition of the second material may differ from a composition of the matrix material and a melting point of the second material may be high, and thus, the second material and the matrix material may not react therebetween in TGG. Accordingly, a crystal orientation of the first material 14 may be randomly arranged.

The second material 15 according to an aspect of the present disclosure may be configured or manufactured by a method of preparing a seed, which will be described below with reference to FIGS. 2 and 4.

The first electrode layer 12 and the second electrode layer 13 may be provided to face each other with the piezoelectric device layer PL therebetween. For example, the first electrode layer 12 may be provided at a first surface (or a lower surface) of the piezoelectric device layer PL, and the second electrode layer 13 may be provided at a second surface (or an upper surface), differing from the first surface, of the piezoelectric device layer PL. The piezoelectric device layer PL according to an aspect of the present disclosure may function as the piezoelectric device 10, based on the first electrode layer 12 and the second electrode layer 13 provided at the first surface (or the lower surface) and the second surface (or the upper surface).

According to an aspect of the present disclosure, because the piezoelectric device 10 does not include lead (Pb), a production restriction material may be reduced, and replacement of a harmful material may be implemented.

According to an aspect of the present disclosure, because the piezoelectric device 10 does not include Pb and has a high piezoelectric characteristic, the piezoelectric device 10 may be driven with a low driving voltage, and thus, a piezoelectric characteristic thereof may be enhanced and power consumption may decrease.

According to an aspect of the present disclosure, the piezoelectric device 10 may emit light in vibrating, thereby enhancing an aesthetic effect.

According to an aspect of the present disclosure, the piezoelectric device 10 may increase a visual effect in a secondary display apparatus, a mood lamp, haptic, and gaming, based on a combination of display products, thereby enhancing reality and immersion.

According to an aspect of the present disclosure, the piezoelectric device 10 may be applied to furniture, a wall, an interior, a roof of a vehicle, a door trim of a vehicle, and an interior/exterior material of a vehicle and may provide a complex function (or a vibration function and an emission function) and an aesthetic function.

FIG. 2 illustrates a method of manufacturing a piezoelectric device according to an aspect of the present disclosure. This illustrates a method of manufacturing a piezoelectric material composition according to an aspect of the present disclosure described above with reference to FIG. 1.

Referring to FIG. 2, a method of manufacturing a piezoelectric material composition according to an aspect of the present disclosure may include a step S101 of preparing an emission seed and a matrix material of a piezoelectric material composition, a step S102 of mixing the matrix material with the emission seed to prepare a slurry, a step S103 of molding the slurry to prepare a green tape, a step S104 of sintering the green tape to prepare a sinter, and a step S105 of forming an electrode in a sintered piezoelectric material composition. The piezoelectric material composition may be expressed as Equation 1 or 2 described above with reference to FIG. 1.

According to an aspect of the present disclosure, the matrix material may be the first material, and the seed may be the second material. Hereinafter, for convenience of description, the first material may be referred to as a matrix material, and the second material may be referred to as a seed.

The matrix material (or the first material) may be a condition where the seed (or the second material) is excluded in Equation 1 described above with reference to FIG. 1 and may be prepared by a method S10 of preparing the matrix material, which will be described below.

According to an aspect of the present disclosure, the seed may have a composition of NaNbO₃:Eu or BaMgAl₁₀O₁₇:Eu and may have a size of 10 μm or more, but aspects of the present disclosure are not limited thereto. For example, the seed may be one of the second materials described above with reference to FIG. 1. For example, the emission seed may be added to the piezoelectric material composition of Equation 1 or 2 by 5 mol % or less, but aspects of the present disclosure are not limited thereto. The see may be prepared by a method S20 of preparing the seed, which will be described below.

Subsequently, the method may include the step S102 of mixing the matrix material with the seed to prepare the slurry. The step S102 of mixing the matrix material with the seed to prepare the slurry may include a step of preparing the slurry including the matrix material and a step of mixing the seed with the matrix material.

The step of preparing the slurry including the matrix material may add an appropriate amount of dispersant and solvent to the matrix material having a composition of Equation 3 or 4 described above with reference to FIG. 1. For example, the solvent may include one or more of ethanol, methanol, isopropanol, MEK, toluene, and distilled water, but aspects of the present disclosure are not limited thereto. By adding an appropriate amount of dispersant and solvent to the matrix material, a slurry where the matrix material is well dispersed in the solvent may be prepared. According to an aspect of the present disclosure, a dispersant may be used for decreasing the viscosity of a slurry including the matrix material. For example, the step of preparing the slurry including the matrix material may further include a step of adding an appropriate amount of binder and plasticizer.

The binder may provide the stiffness, flexibility, ductility, durability, tenacity, and smoothness of a green tape. The binder may include at least one of polyvinylbuthylal (PVB) resin, polyvinyl alcohol (PVA), and polyethylene glycol (PEG), but aspects of the present disclosure are not limited thereto and a binder known to those skilled in the field of piezoelectric material composition may be used.

The plasticizer may be added for providing the elasticity and plastic characteristic of the green tape. The plasticizer may include at least one of phthalate-based plasticizer, adipate-based plasticizer, phophate-based plasticizer, polyether-based plasticizer, and polyester-based plasticizer, but aspects of the present disclosure are not limited thereto and a plasticizer material known to those skilled in the field of piezoelectric material composition may be used.

A step of mixing the seed material with the matrix material may be a step of mixing the seed with the slurry including the matrix material which is prepared in a previous step and may be performed at a low speed in a state where there is no ball.

An aspect of the present disclosure may further include an aging step and a degassing step of removing an air bubble and a gas.

The degassing step may be a step of adjusting the slurry to have appropriate viscosity for a molding process, in a below-described step of molding a piezoelectric material. For example, the degassing step may be adjusted to have a viscosity of 1,000 cPs to 3,000 cPs (centipoise) by using a vacuum stirrer at a room temperature. The aging step may be a step of adjusting a temperature to a room temperature again because the slurry is cooled when a solvent is volatilized in the degassing step. Accordingly, a piezoelectric material having a slurry form may be configured.

Subsequently, a step S103 of molding the slurry to prepare a green tape may include a step of manufacturing the green tape having a certain volume and shape by using a slurry (or a piezoelectric material) prepared in the step S102 where the matrix material and the seed material are mixed with each other.

For example, a step of molding the slurry (or the piezoelectric material) to prepare a green tape may include a step of tape-casting a piezoelectric material, a step of performing primary molding on the tape-casted piezoelectric material, and a step of performing secondary molding on a primarily-molded piezoelectric material.

The tape casting step may be a step of tape-casting a slurry where the matrix material prepared in a previous step is mixed with a seed, by using a tape casting device (or a blade).

A step of performing primary molding on the tape-casted piezoelectric material may be performed through warm isostatic press (WIP), and a step of performing secondary molding on the tape-casted piezoelectric material may be performed through cold isostatic press (CIP) and may be used for increasing a density of a sinter in a sintering step described below. In the piezoelectric material composition according to an aspect of the present disclosure, the WIP may be performed in a case where a green tape is prepared based on stack and lamination such as tape casting.

The step S103 of molding the piezoelectric material may further include a degreasing step after primary molding. The degreasing step may be a step of removing a solvent or an organic material. For example, in the degreasing step, a temperature and a maintenance time of a furnace may be set based on the kinds of dispersant, binder, and plasticizer used therein.

The step S103 of molding the piezoelectric material may include a step of performing secondary molding after the degreasing step. For example, the secondary molding step may be performed through cold isostatic press (CIP).

Subsequently, the step S104 of sintering the green tape to prepare the sinter may be performed in one temperature period, and then, may be cooled.

Subsequently, the step S105 of forming an electrode in the sinter may form the electrode on a first surface of a piezoelectric material sinter, which is prepared in a previous step, and a second surface, which is opposite to (or different from) the first surface, of the piezoelectric material sinter. For example, the electrode may be formed by coating a transparent electrode, but aspects of the present disclosure are not limited thereto and the electrode may be used without being limited. For example, the transparent electrode may be indium tin oxide (ITO), PEDOT:PSS, silver nanowire (AgNW), or a metal mesh, but aspects of the present disclosure are not limited thereto.

According to an aspect of the present disclosure, in the method of manufacturing the piezoelectric device, because the piezoelectric device layer does not include Pb and has a high piezoelectric characteristic, the piezoelectric device layer may be driven with a low driving voltage, and thus, a piezoelectric characteristic thereof may be enhanced.

According to an aspect of the present disclosure, in the method of manufacturing the piezoelectric device, time and cost may be largely reduced compared to a method of manufacturing a single crystal, thereby considerably enhancing productivity.

According to an aspect of the present disclosure, in the method of manufacturing the piezoelectric device, productivity may be enhanced, and thus, optimization of a manufacturing process may be implemented.

According to an aspect of the present disclosure, in the method of manufacturing the piezoelectric device, because the piezoelectric device layer does not include Pb, a production restriction material may be reduced and replacement of a harmful material may be implemented, and thus, an environment-friendly piezoelectric material composition may be provided.

FIG. 3 illustrates a method of manufacturing a matrix material in a method of manufacturing a piezoelectric device according to an aspect of the present disclosure. This illustrates a method of manufacturing the matrix material of the piezoelectric device layer of FIG. 2.

Referring to FIG. 3, a method of manufacturing a matrix material of a piezoelectric material composition according to an aspect of the present disclosure may include a step S11 of weighing raw materials, a step S12 of mixing the weighed raw materials, a calcination and synthesis step S13 of synthesizing the mixed raw materials, a step S14 of milling a synthesized matrix material. In the following description, a condition based on the method of manufacturing the piezoelectric material composition may include, for example, a temperature, pressure, and a time, but aspects of the present disclosure are not limited thereto.

First, in the method of manufacturing the matrix material of the piezoelectric material composition according to an aspect of the present disclosure, the step S11 of weighing the raw material may be a step of weighing a raw material on the basis of a mole ratio to add an appropriate amount of solvent. For example, the matrix material according to an aspect of the present disclosure may satisfy Equation 3 or 4 described above with reference to FIG. 1. For example, the matrix material may be a KNN-based material. For example, the matrix material may be (Na, K, Sr, Bi, Ag) (Nb, Sb, Zr)O₃, but aspects of the present disclosure are not limited thereto. The step S11 of weighing the raw material may be performed independently of a manufacturing method, or may be omitted.

For example, a raw material of the matrix material may include sodium carbonate (Na₂CO₃), potassium carbonate (K₂CO₃), niobium oxide (Nb₂O₅), antimony oxide (Sb₂O₃), strontium carbonate (SrCO₃), zirconium oxide (ZrO₂), calcium carbonate (CaCO₃), bismuth oxide (Bi₂O₃), and silver oxide (Ag₂O). However, aspects of the present disclosure are not limited thereto. For example, the raw material may include oxide other than carbonate including a corresponding positive ion (for example, Na⁺, K⁺, Nb⁺⁵, Sb⁺³, Ca⁺², Sr⁺², and Zr+⁴). For example, the step S11 of weighing the raw material may be process which weighs the raw material on the basis of a mole ratio of a composition to synthesize, puts the weighed raw material into a nylon jar, and adds an appropriate amount of solvent (for example, ethanol), but aspects of the present disclosure are not limited thereto.

Subsequently, the step S12 of mixing the raw materials may be a step of mixing and milling the weighed raw material and ethanol by using a ball mill process.

An aspect of the present disclosure may further include a drying step of separating a powder mixed with the solvent after the mixing step. Accordingly, in an aspect of the present disclosure, ethanol mixed with the raw material may be removed.

Subsequently, an aspect of the present disclosure may include a step S13 of calcining the raw material. The step of calcining the raw material may be a step of phase-synthesizing primarily mixed raw materials. Accordingly, in an aspect of the present disclosure, carbonate of the raw material may be removed, and the raw material may uniformly react to form a uniform perovskite phase.

Subsequently, the step S14 of milling the phase-synthesized matrix material may be a step of putting the phase-synthesized matrix material into bottle along with a solvent (ethanol) and milling the phase-synthesized matrix material by using a ball mill process to form small particles.

Moreover, the milling step may further include a drying step of separating a powder mixed with the solvent after the milling step. Here, the drying step may put the milled matrix material into a dish and may dry the milled matrix material at a temperature of 100° C. For example, drying may be performed for 3 hours, but aspects of the present disclosure are not limited thereto.

Also, according to an aspect of the present disclosure, the step S14 of milling the phase-synthesized matrix material may further include a step of sieving a material.

The sieving step may be a step of filtering out dried powders finely grinded by the mortar by using a 40-mesh sieve to produce powders including particles having a certain size or less. A powder passing through the 40-mesh sieve may have a size of 400 μm or less, but aspects of the present disclosure are not limited thereto.

Therefore, the matrix material according to an aspect of the present disclosure may be prepared.

FIG. 4 illustrates a method of manufacturing a seed in a method of manufacturing a piezoelectric device according to an aspect of the present disclosure. This illustrates a method of manufacturing a seed of the piezoelectric device layer of FIG. 2.

Referring to FIG. 4, a method of manufacturing a seed of a piezoelectric material composition according to an aspect of the present disclosure may include a step S21 of primarily weighing a raw material, a step S22 of preparing a secondary seed, a step S23 of performing secondary weighing, and a step S24 of preparing a seed. First, the step S21 of primarily weighing the raw material may be a step of weighing a raw material of the secondary seed on the basis of a mole ratio to add an appropriate amount of solvent. For example, the secondary seed may be a BNN seed, and the primarily weighing step S21 may be a step of weighing a raw material of the BNN seed which is the secondary seed. For example, a mole ratio of a composition to be synthesized in the secondary seed may be (Bi_{2.5}Na_{3.5})Nb₅O₁₆. Hereinafter, therefore, the secondary seed may be referred to as a “BNN seed”. For example, the step S21 of weighing the raw material may be performed independently of a manufacturing method, or may be omitted. For example, the step of primarily weighing the raw material may weigh Na₂CO₃, Nb₂O₅, Bi₂O₃, and sodium chloride (NaCl), based on a mole ratio of a composition which is to be synthesized. Also, a raw material such as Eu₂O₃, Sm₂O₃, and Tb₂O₃ each including a rare-earth material may be weighed based on a mole ratio of a composition which is to be doped. For example, the raw material weighed in the weighing step may be put into a nylon jar, and then, an appropriate amount of solvent may be added thereto. For example, the solvent may be ethanol, but aspects of the present disclosure are not limited thereto.

Moreover, in the primary weighing step, a ratio of Na₂CO₃, Nb₂O₅, Bi₂O₃, and NaCl may be adjusted. For example, a ratio of NaCl to oxide including Na₂CO₃, Nb₂O₅, and Bi₂O₃ may be 1:1.5, but aspects of the present disclosure are not limited thereto.

The step S22 of preparing the secondary seed (or the BNN seed) may further include a step of mixing materials which are weighed in a previous step and a step of phase-synthesizing mixed raw materials.

For example, the mixed raw material may be mixed with a solvent and may be mixed and milled for 12 hours by using a ball mill process, but aspects of the present disclosure are not limited thereto. Also, the step of mixing the raw materials may further include a drying step of separating a powder mixed with the solvent after the mixing and milling step is completed. Here, the drying step may put the primarily mixed raw material into a dish and may sufficiently dry the mixed raw material at a temperature of 100° C., but aspects of the present disclosure are not limited thereto.

For example, the phase-synthesizing step may be a step of finely grinding a compound with a mortar after mixing and drying the raw material, putting the grinded compound into an alumina crucible, increasing a temperature of the grinded compound in an electric furnace at a temperature increasing speed of 5° C./min, calcining the compound for 6 hours at 1,100° C. to 1,175° C., and cooling or naturally cooling the calcined compound at a room temperature, but aspects of the present disclosure are not limited thereto. A calcination-completed secondary seed (or BNN seed) may have a plate-shaped particle. Here, the step of phase-synthesizing the raw material may be referred to as primary calcination.

The step S22 of preparing the secondary seed (or BNN seed) may further include a step of cleaning a calcination-completed secondary seed.

For example, the step of cleaning the secondary seed may clean and filter the secondary seed two to ten times by using water of 80° C. or more to remove NaCl stained on a secondary seed powder, but aspects of the present disclosure are not limited thereto.

Subsequently, the secondary weighing step S23 may be a step of putting an appropriate amount of solvent and a material including Na for substituting Bi of the secondary seed (or BNN seed) powder and performing weighing on the basis of a mole ratio of a composition. For example, a composition of a seed according to an aspect of the present disclosure may be NaNbO₃:Eu. Hereinafter, therefore, a seed may be referred to as an “NN seed (NaNbO₃)” or “NN seed (NaNbO₃)” including a rare-earth material.

For example, in the secondary weighing step, Na₂CO₃ and NaCl may be weighed based on a mole ratio of a composition which is to be synthesized and may be put into a beaker, and then, an appropriate amount of solvent may be added thereto. For example, the solvent may be ethanol, but aspects of the present disclosure are not limited thereto.

Subsequently, the step S24 of preparing the seed (or NN seed) may include a step of mixing secondarily weighed materials and performing a topochemical reaction.

For example, the step of mixing the secondarily weighed materials may be performed through a stirring process and may be performed for 6 hours with 80 rpm in a state where a magnetic bar is put into a beaker, but aspects of the present disclosure are not limited thereto.

Moreover, the step of preparing the seed (or NN seed) may further include a step of drying a mixed secondarily weighed material. Here, the drying step may put a compound into a dish and may dry the compound for 3 hours at a temperature of 100° C., but aspects of the present disclosure are not limited thereto.

For example, the step of performing the topochemical reaction may put a dried seed material into a crucible and may be performed for 6 hours at 975° C., but aspects of the present disclosure are not limited thereto. By performing the topochemical reaction, Bi included in the secondary seed (or BNN seed) may be replaced with Na. The topochemical reaction will be described below in detail with reference to FIG. 6.

Here, the step of performing the topochemical reaction may be referred to as secondary calcination.

The step S24 of preparing the seed (or NN seed) according to an aspect of the present disclosure may further include a step of cleaning a seed (or NN seed) on which the topochemical reaction is completed.

For example, the step of cleaning the seed (or NN seed) may clean and filter the seed five to ten times by using water of 80° C. or more to remove NaCl stained on the NN seed, but aspects of the present disclosure are not limited thereto.

Moreover, even after cleaning and filtering, acid treatment may be performed with nitric acid several times to remove Bi remaining in the seed (or NN seed), and then, neutralization cleaning may be performed with water. For example, nitric acid may be put into a beaker, the seed (or NN seed) may be put, and shaking may be performed at every 10 minutes. This may be repeatedly performed for 1 hour to 2 hours, but aspects of the present disclosure are not limited thereto. For example, there may be a problem where a distribution of sizes of NN seeds is not constant due to a surface stripping phenomenon in an acid treatment process of removing Bi ions in the NN seed. Accordingly, by adjusting a ratio of NaCl and an oxide powder, performing filtering, and performing an acid treatment process twice or more, a problem where a distribution of sizes of NN seeds is not constant may be solved.

Therefore, an aspect of the present disclosure may prepare a seed including a rare-earth material.

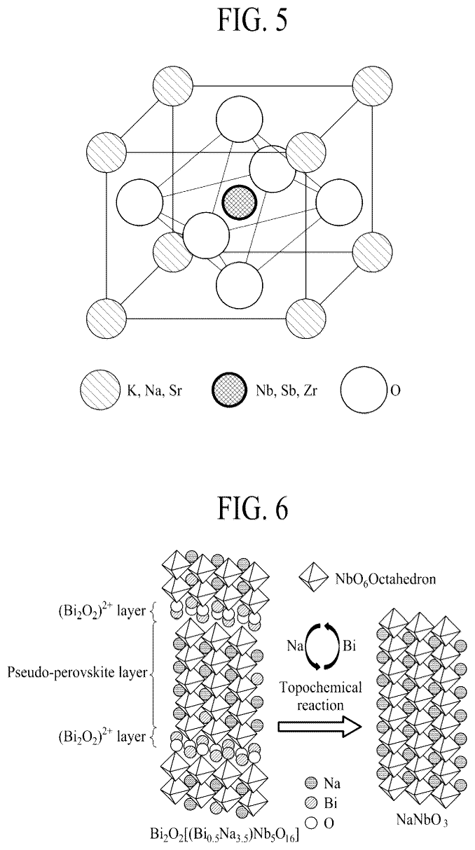

FIG. 5 illustrates a crystal structure of a piezoelectric device layer according to an aspect of the present disclosure.

Referring to FIG. 5, a piezoelectric material based on a composition of Equation 1 according to the present disclosure may have a structure of ABX₃. Here, A may be a first positive ion, B may be a second positive ion, and X may be a negative ion which is bonded thereto. The first positive ion may be kalium (K⁺), sodium (Na⁺), strontium (Sr⁺²), bismuth (Bi⁺³), or silver (Ag⁺), the second positive ion may be niobium (Nb⁺⁵), antimony (Sb⁺³), or a zirconium (Zr⁺⁴), and the negative ion may be oxygen (O⁻²). The first positive ion and the negative ion may configure a cube-octahedral structure of AX₁₂, and the second positive ion may be BX₆ and may have a structure bonded in an octahedral structure.

FIG. 6 illustrates a grain variation of a seed material occurring in a step of preparing the seed of FIG. 4 according to an aspect of the present disclosure. In FIG. 6, a crystal structure having a composition of Bi₂O₂[(Bi_{0.5}Na_{3.5})Nb₅O₁₆] illustrated in a left region shows a secondary seed (or BNN seed). In FIG. 6, a crystal structure having a composition of NaNbO₃ illustrated in a right region shows a seed (or NN seed).

Referring to FIG. 6, the crystal structure of the secondary seed (or BNN seed) having a composition of Bi₂O₂[(Bi_{0.5}Na_{0.5})Nb₅O₁₆] may be a structure where a layer where an NbO₆ octahedron and Na and Bi are provided between NbO₆ octahedrons are provided from an upper portion, a (Bi₂O₂)²⁺ layer, a pseudo-perovskite layer, and a layer where a (Bi₂O₂)²⁺ layer, an NbO₆ octahedron, and Na and Bi provided between NbO₆ octahedrons are repeated. Subsequently, a crystal structure of the secondary seed having a composition of NaNbO³ may have a structure which is surrounded by the Na with an NbO₆ octahedron therebetween.

In the step S24 of preparing the seed (or NN seed), the secondary seed (or BNN seed) may be changed to the seed (or NN seed) by a topochemical reaction in the step of preparing the seed (or NN seed) of FIG. 6. Here, the topochemical reaction may denote a chemical reaction where a direction of orientation of a mother grain and a grain direction of orientation of a product has different relationships in direction of orientation but a shape of a crystal particle is maintained, in a solid-phase chemical reaction.

Therefore, as shown in FIG. 6, in a process of substituting a Bi element of the secondary seed (or BNN seed) into an Na element, all of a layer where an NbO₆ octahedron and Na and Bi are provided between NbO₆ octahedrons are provided, a (Bi₂O₂)²⁺ layer, and a pseudo-perovskite layer, and a layer where a (Bi₂O₂)²⁺ layer, an NbO₆ octahedron, and Na and Bi provided between NbO₆ octahedrons are repeated may be changed to a single structure having a composition of NaNbO₃.

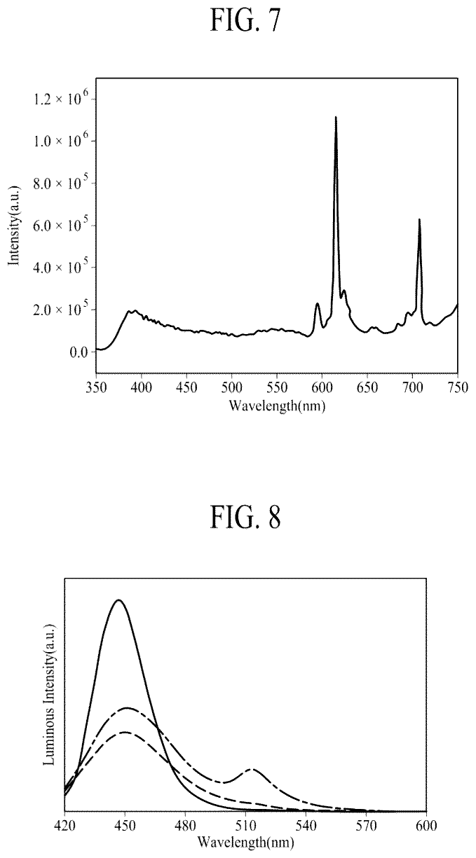

FIG. 7 illustrates a wavelength range of a seed according to an aspect of the present disclosure. A seed of FIG. 7 according to an aspect of the present disclosure may be manufactured by the manufacturing method of FIGS. 2 to 4. In FIG. 7, intensity (a. u.) of the Y axis is a numerical value expressed as a relative value with respect to a maximum value of an emission spectrum.

Referring to FIG. 7, a seed (or NN seed) according to an aspect of the present disclosure may include NaNbO₃:Eu. For example, according to an aspect of the present disclosure, the seed may be a material where a small amount of rare-earth material (for example, Eu, Pr, La, Er, Tb, etc.) is added to a NaNbO₃ particle. For example, the rare-earth material may be 3 mol % or less with respect to the seed, but aspects of the present disclosure are not limited thereto. Accordingly, a piezoelectric characteristic of a piezoelectric device layer may be enhanced.

Therefore, according to an aspect of the present disclosure, a small amount of rare-earth material may be added to a (001) plate structure, and the physical properties of a seed material may be intactly maintained, thereby realizing a characteristic where light is emitted in energy excitation. For example, a wavelength of NaNbO₃:Eu may be within a range of 600 nm to 650 nm.

Therefore, a seed according to an aspect of the present disclosure may emit red light. For example, the excitation of an electron may occur whenever a direction of an electric field is changed, and thus, when a piezoelectric device is driven, haptic and an emission effect may all be implemented. For example, when an electron is excited by intensity of an electric field generated in a fluorescent layer and the excited electron returns to a stable state, the electron may emit energy and may emit light.

Therefore, because a piezoelectric device layer includes a light emitting material, a piezoelectric device according to an aspect of the present disclosure may implement haptic and may enhance an aesthetic effect.

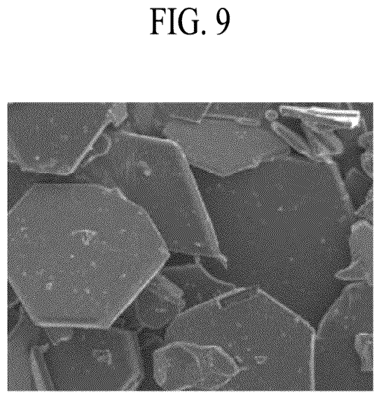

FIG. 8 illustrates a wavelength range of a seed according to another aspect of the present disclosure. FIG. 9 illustrates a microstructure of the seed illustrated in FIG. 8 according to another aspect of the present disclosure. In FIG. 8, luminance intensity (a. u.) of the Y axis is a numerical value expressed as a relative value with respect to a maximum value of an emission spectrum.

A seed according to an aspect of the present disclosure may be manufactured by the manufacturing method of FIGS. 2 to 4. In FIG. 8, a solid line represents Sr₃(PO₄)₅Cl:Eu²⁺, a dash-single dotted line represents BaMgAl₁₀O₁₇:Eu²⁺Mn²⁺, and a dotted line represents BaMgAl₁₀O₁₇:Eu²⁺. The piezoelectric device layer illustrated in FIGS. 8 and 9 may be manufactured by TGG. For example, in a case where the piezoelectric device layer is manufactured by TGG, the dissipation of a second material used as a seed may be reduced, and thus, emission efficiency may be enhanced.

Referring to FIGS. 8 and 9, a seed according to another aspect of the present disclosure may be Sr₃(PO₄)₅Cl:Eu²⁺, BaMgAl₁₀O₁₇:Eu²⁺Mn²⁺, and BaMgAl₁₀O₁₇:Eu²⁺. Here, the seed may be a material where a rare-earth material is added to Sr₃(PO₄)₅Cl or BaMgAl₁₀O₁₇. For example, the rare-earth material may be Eu²⁺ or Eu²⁺Mn²⁺.

According to an aspect of the present disclosure, the seed may be a seed where a small amount of rare-earth material (for example, Eu, Pr, La, Er, Tb, etc.) is doped on a Sr₃(PO₄)₅Cl particle. As another example, the seed may be a seed where a small amount of rare-earth material (for example, Eu, Pr, La, Er, Tb, etc.) is doped on a BaMgAl₁₀O₁₇ particle. For example, Sr₃(PO₄)₅Cl or BaMgAl₁₀O₁₇ may have a plate structure having a size of about 10 μm or more, but aspects of the present disclosure are not limited thereto. Accordingly, according to an aspect of the present disclosure, a small amount of rare-earth material may be added to a seed material having a plate structure, and thus, the physical properties of the seed material may be intactly maintained, thereby realizing a characteristic where light is emitted in energy excitation.

Referring to FIG. 8, a wavelength range of a seed according to another aspect of the present disclosure may be 420 nm to 480 nm. Therefore, the seed according to another aspect of the present disclosure may emit blue light. For example, the excitation of an electron may occur whenever a direction of an electric field is changed, and thus, when a piezoelectric device is driven, haptic and an emission effect may all be implemented. For example, when an alternating current (AC) voltage is applied to a piezoelectric device layer including a light emitting material, an electron is excited by intensity of an electric field generated in a fluorescent layer and the excited electron returns to a stable state, the electron may emit energy and may emit light.

Accordingly, in the piezoelectric device according to another aspect of the present disclosure because the piezoelectric device layer includes the light emitting material, haptic and an aesthetic effect may be enhanced. Also, another aspect of the present disclosure may variously change an emission color of the piezoelectric device layer, based on a seed material.

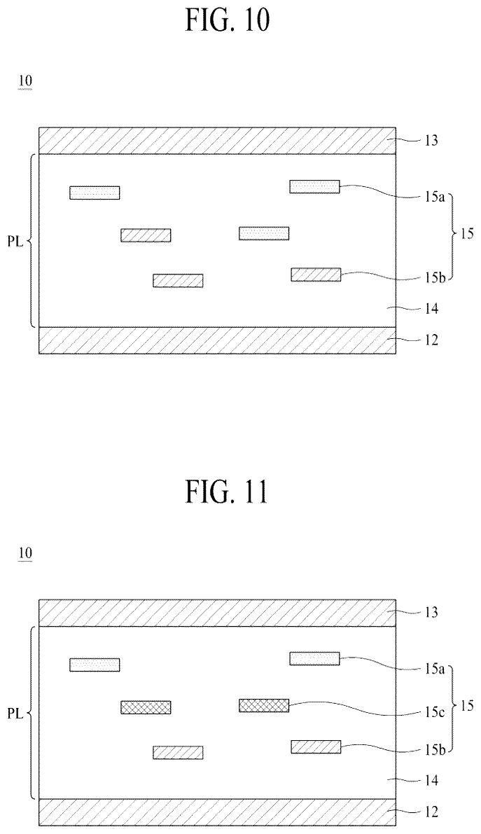

FIG. 10 is a cross-sectional view illustrating a piezoelectric device according to another aspect of the present disclosure. Except for a configuration of a second material (or a seed), the piezoelectric device according to another aspect of the present disclosure may be substantially the same as the piezoelectric device according to an aspect of the present disclosure described above with reference to FIG. 1. Hereinafter, therefore, like reference numerals refer to like elements, and only different elements will be described.

Referring to FIG. 10, a second material 15 may include a first seed 15a and a second seed 15b. The first seed 15a and the second seed 15b may include different materials. For example, the first seed 15a may be a seed which emits red light, and the second seed 15b may be a seed which emits green light. For example, the first seed 15a according to another aspect of the present disclosure may be Y₂O₃:Eu. For example, the second seed 15b according to another aspect of the present disclosure may be Y₂SiO₅:Tb. Accordingly, a piezoelectric device layer PL according to another aspect of the present disclosure may emit yellow light.

As another example, the first seed 15a may be a seed which emits red light, and the second seed 15b may be a seed which emits blue light. For example, the first seed 15a may be Y₂O₃:Eu, and the second seed 15b may be BaMgAl₁₀O₁₇:Eu. Accordingly, the piezoelectric device layer PL according to another aspect of the present disclosure may emit magenta light. However, aspects of the present disclosure are not limited thereto.

For example, a content (or a mix ratio) of each of the first seed 15a and the second seed 15b according to an aspect of the present disclosure may be equal to each other. For example, a content (or a mix ratio) of each of the first seed 15a and the second seed 15b dispersed in a first material (or a matrix material) may be equal to each other. However, aspects of the present disclosure are not limited thereto, and a content (or a mix ratio) of each of the first seed 15a and the second seed 15b dispersed in a first material (or a matrix material) may be variously set. For example, a content (or a mix ratio) of each of the first seed 15a and the second seed 15b may be changed based on a color of light which is to be emitted.

According to another aspect of the present disclosure, because a small amount of rare-earth material is doped on a seed material having a plate shape, the piezoelectric device 10 may intactly maintain the physical properties of the seed material and may have a characteristic where light is emitted in energy excitation.

According to another aspect of the present disclosure, the piezoelectric device 10 may include the first seed 15a and the second seed 15b including different light emitting materials, and thus, may control a color of light emitted from the piezoelectric device 10. Accordingly, the piezoelectric device 10 according to another aspect of the present disclosure may implement an aesthetic effect which is more enhanced.

FIG. 11 is a cross-sectional view illustrating a piezoelectric device according to another aspect of the present disclosure. Except for a configuration of a second material (or a seed), the piezoelectric device according to another aspect of the present disclosure may be substantially the same as the piezoelectric device according to an aspect of the present disclosure described above with reference to FIG. 1. Hereinafter, therefore, like reference numerals refer to like elements, and only different elements will be described.

Referring to FIG. 11, according to another aspect of the present disclosure, a second material 15 may include a first seed 15a, a second seed 15b, and a third seed 15c. The first seed 15a, the second seed 15b, and the third seed 15c may include different materials which emit lights of different colors. For example, the first seed 15a may be a seed which emits red light, the second seed 15b may be a seed which emits green light, and the third seed 15c may be a seed which emits blue light. For example, the first seed 15a according to another aspect of the present disclosure may be Y₂O₃:Eu, the second seed 15b may be Y₂SiO₅:Tb, and the third seed 15c may be BaMgAl₁₀O₁₇:Eu. Accordingly, a piezoelectric device layer PL according to another aspect of the present disclosure may emit white light. However, aspects of the present disclosure are not limited thereto.

For example, a content (or a mix ratio) of each of the first seed 15a, the second seed 15b, and the third seed 15c according to an aspect of the present disclosure may be equal to one another. However, aspects of the present disclosure are not limited thereto, and a content (or a mix ratio) may be variously set. For example, a content (or a mix ratio) of each of the first seed 15a, the second seed 15b, and the third seed 15c dispersed in a first material (or a matrix material) may differ. For example, a content (or a mix ratio) of each of the first seed 15a and the second seed 15b may be equal to each other, and a content (or a mix ratio) of the third seed 15c may differ. For example, a content (or a mix ratio) of each of the first seed 15a and the third seed 15c may be equal to each other, and a content (or a mix ratio) of the second seed 15b may differ.

According to another aspect of the present disclosure, because a small amount of rare-earth material is doped on a seed material having a plate shape, the piezoelectric device 10 may intactly maintain the physical properties of the seed material having a plate shape and may have a characteristic where light is emitted in energy excitation.

According to another aspect of the present disclosure, the piezoelectric device 10 may include the first seed 15a, the second seed 15b, and the third seed 15c including different light emitting materials, and thus, may control a color of light emitted from the piezoelectric device 10. Accordingly, the piezoelectric device 10 according to another aspect of the present disclosure may implement an aesthetic effect which is more enhanced.

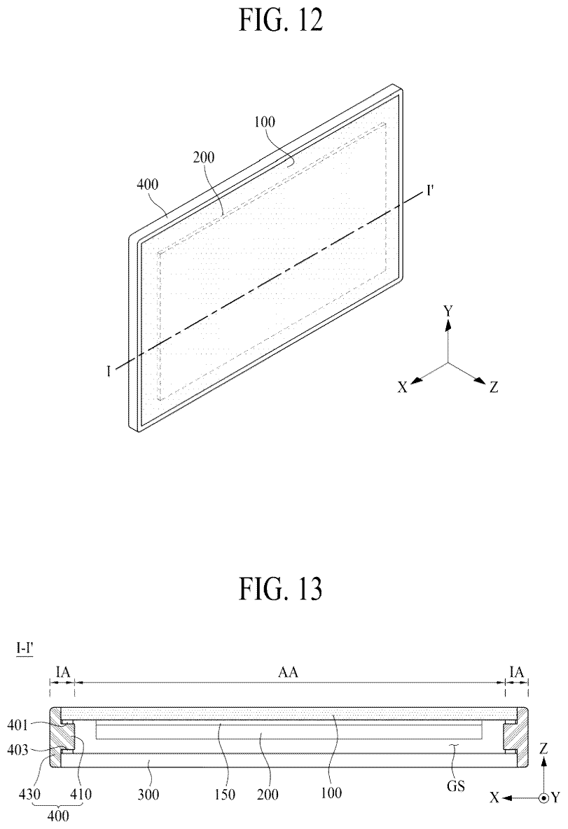

FIG. 12 is a perspective view of an apparatus according to an aspect of the present disclosure. FIG. 13 is a cross-sectional view taken along line I-I′ of FIG. 12 according to an aspect of the present disclosure.

Referring to FIGS. 12 and 13, an apparatus according to an aspect of the present disclosure may implement or realize a sound apparatus, a sound output apparatus, a vibration apparatus, a vibration generating apparatus, a sound bar, a sound system, a sound apparatus for electronic devices, a sound apparatus for display, a sound apparatus for vehicular apparatuses, or a sound bar for vehicular apparatuses. For example, the vehicular apparatus may include one or more seats and one or more glass windows. For example, the vehicular apparatus may include a vehicle, a train, a ship, or an aircraft, but aspects of the present disclosure are not limited thereto. Also, an apparatus according to an aspect of the present disclosure may implement an analog signage or a digital signage such as an advertising signboard, a poster, or a guideboard.

The apparatus according to an aspect of the present disclosure may be an apparatus including a plurality of pixels, but aspects of the present disclosure are not limited thereto.

The display apparatus may include a display panel, including a plurality of pixels implementing a black and white, or color image, and a driver for driving the display panel. Each of the plurality of pixels may be a subpixel configuring one of a plurality of colors implementing a color image. An apparatus according to an aspect of the present disclosure may include a notebook computer, a television (TV), a computer monitor, an equipment apparatus including a specific form of a vehicle or a vehicular or automotive apparatus, and a set device (or a set apparatus) or a set electronic apparatus such as a smartphone or an electronic pad, which are complete products (or final products) including a display panel such as a liquid crystal display panel or an organic light emitting display panel.

Referring to FIG. 12, an apparatus according to an aspect of the present disclosure may include a vibration member 100 and a vibration apparatus 200.

The vibration member 100 may generate a vibration, based on a displacement (or driving or vibration) of the vibration apparatus 200, or may output a sound (or a sound wave). The vibration member 100 may be a vibration object, a display member, a display panel, a signage panel, a passive vibration plate, a front member, a rear member, a vibration panel, a sound panel, a passive vibration panel, a sound output plate, a sound vibration plate, or an image screen, but aspects of the present disclosure are not limited thereto.

For example, the vibration member 100 may include one or more of a display panel including a pixel configured to display an image, a screen panel on which an image is to be projected from a display apparatus, a lighting panel, a signage panel, a vehicular interior material, a vehicular glass window, a vehicular exterior material, a ceiling material of a building, an interior material of a building, a glass window of a building, an interior material of an aircraft, and a glass window of an aircraft. For example, the vibration member 100 may include one or more of wood, plastic, glass, metal, cloth, fiber, paper, rubber, leather, carbon, and mirror.

Hereinafter, an example where the vibration member 100 is a display panel will be described.

The display panel 100 may display an image, and for example, may display an image (for example, an electronic image, a digital image, a still image, or a video image). For example, the display panel 100 may emit light to display an image. The display panel 100 may be a curved display panel or all types of display panels such as a liquid crystal display panel, an organic light emitting display panel, a quantum dot light emitting display panel, a micro light emitting diode display panel, and an electrophoresis display panel. The display panel 100 may be a flexible display panel. For example, the display panel 100 may be a flexible light emitting display panel, a flexible electrophoresis display panel, a flexible electro-wetting display panel, a flexible micro light emitting diode display panel, or a flexible quantum dot light emitting display panel, but aspects of the present disclosure are not limited thereto.

The display panel 100 according to an aspect of the present disclosure may include a display area AA which displays an image on the basis of driving of a plurality of pixels. Also, the display panel 100 may include a non-display area IA which surrounds the display area AA, but aspects of the present disclosure are not limited thereto. For example, the non-display area IA may be at a periphery of the display area AA.

The vibration apparatus 200 may be configured to vibrate the display panel 100. For example, the vibration apparatus 200 may vibrate the display panel 100 at the rear surface of the display panel 100, and thus, may provide a user with a sound and/or a haptic feedback on the basis of a vibration of the display panel 100. The vibration apparatus 200 may be implemented at the rear surface of the display panel 100 to directly vibrate the display panel 100.

According to an aspect of the present disclosure, the vibration apparatus 200 may vibrate based on a vibration driving signal synchronized with an image displayed by the display panel 100, thereby vibrating the display panel 100. According to another aspect of the present disclosure, the vibration apparatus 200 may vibrate based on a haptic feedback signal (or a tactile feedback signal) synchronized with a user touch applied to a touch panel (or a touch sensor layer) which is disposed on the display panel 100 or embedded in the display panel 100, and thus, may vibrate the display panel 100. Accordingly, the display panel 100 may vibrate based on a vibration of the vibration apparatus 200 to provide a user (or a viewer) with one or more of a sound and a haptic feedback.

The vibration apparatus 200 according to an aspect of the present disclosure may be implemented to have a size corresponding to the display area AA of the display panel 100. A size of the vibration apparatus 200 may be 0.9 to 1.1 times a size of the display area AA of the display panel 100, but aspects of the present disclosure are not limited thereto. For example, a size of the vibration apparatus 200 may be less than or equal to that of the display area AA. For example, a size of the vibration apparatus 200 may be equal to or almost equal to that of the display area AA of the display panel 100, and thus, may cover a large region of the display panel or the display panel 100 and a vibration generated by the vibration apparatus 200 may vibrate a whole region of the display panel 100, thereby enhancing satisfaction of a user and increasing a sense of orientation of a sound. Also, a contact area (or a panel coverage) between the display panel 100 and the vibration apparatus 200 may increase, and thus, a vibration region of the display panel 100 may increase, thereby enhancing a sound of a middle-low pitched sound band generated based on a vibration of the display panel 100. Also, the vibration apparatus 200 applied to a large-sized apparatus may vibrate all of the display panel 100 having a large size (or a large area), and thus, a sense of orientation of a sound based on a vibration of the display panel 100 may be more enhanced, thereby realizing an enhanced sound effect. Accordingly, the vibration apparatus 200 according to an aspect of the present disclosure may be disposed at the rear surface of the display panel 100 to sufficiently vibrate the display panel 100 in a vertical (or forward and rearward) direction, thereby outputting a desired sound in a forward direction of the apparatus or the display apparatus.

The vibration apparatus 200 according to an aspect of the present disclosure may be implemented as a film type. Because the vibration apparatus 200 is implemented as a film type, the vibration apparatus 200 may have a thickness which is thinner than the display panel 100, thereby minimizing an increase in thickness of the apparatus caused by the arrangement of the vibration apparatus 200. For example, the vibration apparatus 200 may be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a sound vibration plate, but aspects of the present disclosure are not limited thereto.

In another aspect of the present disclosure, the vibration apparatus 200 may not be disposed at the rear surface of the display panel 100 and may be applied to a vibration object instead of the display panel 100. For example, the vibration object may be a non-display panel, a mirror, an interior material of a vehicle, a glass window of a vehicle, an indoor ceiling of a building, a glass window of a building, an interior material of an aircraft, or a glass window of an aircraft, but aspects of the present disclosure are not limited thereto. For example, the vibration object may be a sound panel or a sound plate including one or more of wood, metal, plastic, glass, cloth, paper, fiber, rubber, leather, and carbon, but aspects of the present disclosure are not limited thereto. For example, the non-display panel may be a light emitting diode lighting panel (or apparatus), an organic light emitting lighting panel (or apparatus), or an inorganic light emitting lighting panel (or apparatus), but aspects of the present disclosure are not limited thereto. In this case, a vibration object may be applied as a vibration plate, and the vibration apparatus 200 may vibrate the vibration object to output a sound.

Referring to FIG. 13, an apparatus according to an aspect of the present disclosure may include a connection member 150 between a vibration apparatus 200 and a display panel 100.

The connection member 150 may include at least one base member and may include an adhesive layer attached on one surface or both surfaces of the base member, or may be configured as a single-layered adhesive layer.

According to an aspect of the present disclosure, the connection member 150 may include a foam pad, a double-sided tape, a double-sided foam tape, or an adhesive, but aspects of the present disclosure are not limited thereto. For example, the adhesive layer of the connection member 150 may include epoxy, acryl, silicone, or urethane, but aspects of the present disclosure are not limited thereto.

The apparatus according to an aspect of the present disclosure may further include a supporting member 300 which is disposed at a rear surface of the display panel 100.

The supporting member 300 may cover the rear surface of the display panel 100. For example, the supporting member 300 may include one or more of a glass material, a metal material, and a plastic material. For example, the supporting member 300 may be a rear structure material or a set structure material. For example, the supporting member 300 may be referred to as the other term such as a cover bottom, a plate bottom, a back cover, a base frame, a metal frame, a metal chassis, a chassis base, or an m-chassis. Therefore, the supporting member 300 may be implemented as an arbitrary type frame or a plate structure material disposed on the rear surface of the display panel 100.

The apparatus according to an aspect of the present disclosure may further include a middle frame 400.

The middle frame 400 may be disposed between a rear edge (or a rear periphery) of the display panel 100 and a front edge portion (or a front periphery portion) of the supporting member 300. The middle frame 400 may support each of one or more of an edge portion (or a periphery portion) of the display panel 100 and an edge portion (or a periphery portion) of the supporting member 300 and may surround one or more of lateral surfaces of each of the display panel 100 and the supporting member 300. The middle frame 400 may provide a gap space GS between the display panel 100 and the supporting member 300. The middle frame 400 may be referred to as a middle cabinet, a middle cover, or a middle chassis, but aspects of the present disclosure are not limited thereto.

The middle frame 400 according to an aspect of the present disclosure may include a first supporting part 410 and a second supporting part 430.

The first supporting part 410 may be disposed between the rear edge (or the rear periphery) of the display panel 100 and the front edge (or the front periphery) of the supporting member 300, and thus, may provide the gap space GS between the display panel 100 and the supporting member 300. A front surface of the first supporting part 410 may be coupled to or connected with the rear edge portion (or the rear periphery portion) of the display panel 100 by a first frame connection member 401. A rear surface of the first supporting part 410 may be coupled to or connected with a front edge portion (or a front periphery portion) of the supporting member 300 by a second frame connection member 403. For example, the first supporting part 410 may have a single picture frame structure having a tetragonal shape, or may include a picture frame structure having a plurality of division bar shapes.

The second supporting part 430 may be vertically coupled to an outer surface of the first supporting part 410 in parallel with a thickness direction Z of an apparatus. The second supporting part 430 may surround one or more of an outer surface of the display panel 100 and an outer surface of the supporting member 300, and thus, may protect the outer surface of each of the display panel 100 and the supporting member 300. The first supporting portion 410 may protrude toward the gap space GS between the display panel 100 and the supporting member 300 from an inner surface of the second supporting part 430.

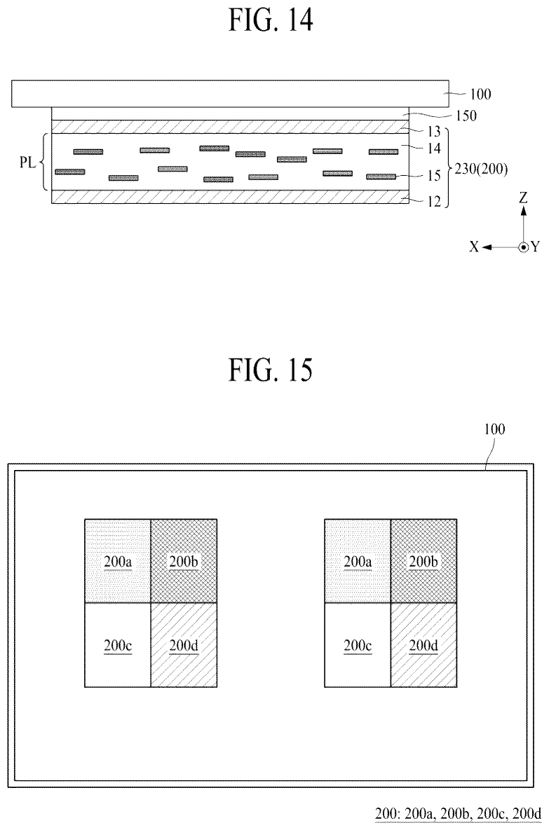

FIG. 14 illustrates a vibration apparatus of FIG. 12 according to an aspect of the present disclosure.

Referring to FIG. 14, a vibration apparatus 200 according to an aspect of the present disclosure may include a piezoelectric device 230. The piezoelectric device 230 may be the same or substantially the same as the piezoelectric device 10 described above with reference to FIGS. 1 to 11, and thus, repeated descriptions thereof are omitted or will be briefly given.

The piezoelectric device 230 may include a piezoelectric device layer PL, a first electrode layer 12 disposed at a first surface of the piezoelectric device layer PL, and a second electrode layer 13 disposed at a second surface, which is opposite to (or different from) the first surface, of the piezoelectric device layer PL.

The piezoelectric device layer PL may include a first material 14 and a second material 15 which is in the first material 14. According to an aspect of the present disclosure, the first material 14 and the second material 15 may form a grain having the same crystal orientation. However, aspects of the present disclosure are not limited thereto, and the piezoelectric device layer PL may have a random crystal orientation, based on the second material 15.

According to an aspect of the present disclosure, the first material 14 may include a matrix material described above with reference to FIGS. 1 to 11, and thus, repeated descriptions thereof are omitted.

According to an aspect of the present disclosure, the second material 15 may include a seed (or NN seed) or an NN seed, to which a rare-earth material is added, described above with reference to FIGS. 1 to 11, and thus, repeated descriptions thereof are omitted.

Therefore, according to an aspect of the present disclosure, the piezoelectric device layer PL may emit light corresponding to a light emitting material simultaneously with a vibration (or a haptic vibration), thereby enhancing an aesthetic effect.

The first electrode layer 12 and the second electrode layer 13 may use a transparent electrode, but aspects of the present disclosure are not limited thereto. For example, the transparent electrode may be ITO, PEDOT:PSS, AgNW, or a metal mesh, but aspects of the present disclosure are not limited thereto. Accordingly, according to an aspect of the present disclosure, light emitted from the piezoelectric device layer PL may be irradiated to the outside, thereby enhancing an aesthetic effect.

Moreover, the piezoelectric device 230 is illustrated as a single layer in FIG. 14, but may be configured to be additionally stacked, based on the desired performance of the piezoelectric device 230. For example, the vibration apparatus 200 may include two or more piezoelectric devices 230. For example, the vibration device 200 may include two or more piezoelectric devices 230 which vertically overlap one another or are stacked. For example, the two or more piezoelectric devices 230 may be configured or polarized (or polling) to be displaced (or vibrated or driven) in the same direction.

FIG. 15 is a plan view of an apparatus including a piezoelectric device according to an aspect of the present disclosure.

Referring to FIG. 15, in an apparatus according to an apparatus according to an aspect of the present disclosure, a vibration apparatus may include a plurality of piezoelectric devices 200a, 200b, 200c, and 200d. For example, each of the plurality of piezoelectric devices 200a, 200b, 200c, and 200d may be the piezoelectric device described above with reference to FIGS. 1 to 11.

Each of the plurality of piezoelectric devices 200a, 200b, 200c, and 200d may include a seed. The seed provided in each of the plurality of piezoelectric devices 200a, 200b, 200c, and 200d may include a rare-earth material. Accordingly, the plurality of piezoelectric devices 200a, 200b, 200c, and 200d according to an aspect of the present disclosure may emit lights of different colors.

An apparatus 100 according to an aspect of the present disclosure may be connected with the plurality of piezoelectric devices 200a, 200b, 200c, and 200d, and thus, may output a sound and/or a vibration (or a haptic vibration), based on vibrations of the plurality of piezoelectric devices 200a, 200b, 200c, and 200d, and may simultaneously emit one or more colors, based on the vibration of each of the plurality of piezoelectric devices 200a, 200b, 200c, and 200d, thereby more enhancing an aesthetic effect.

According to an aspect of the present disclosure, when a driving voltage is applied, the plurality of piezoelectric devices 200a, 200b, 200c, and 200d may implement red, blue, green, and white, based on the kind of rare-earth material added thereto. However, aspects of the present disclosure are not limited thereto.

According to an aspect of the present disclosure, the piezoelectric device 200 may provide a visual function, an acoustic function, and a multifunction (or visual sense or acoustic sense), based on the control of a driving frequency.

Furthermore, according to another aspect of the present disclosure, the piezoelectric device 200 may include an emission-type piezoelectric device and a non-emission piezoelectric device. For example, the emission-type piezoelectric device may include a light emitting material, and the non-emission piezoelectric device may not include a light emitting material. For example, the emission-type piezoelectric device may include a seed material and a light emitting material as a second material. For example, the non-emission piezoelectric device may include a seed material as a second material.

According to another aspect of the present disclosure, by adjusting a composition of a second material, each of the emission-type piezoelectric device and the non-emission piezoelectric device may be manufactured and may be attached on the vibration member 100 to cross, and thus, an acoustic or visual effect may be selectively implemented.

A piezoelectric material composition, a piezoelectric device, a method of manufacturing the same, and an apparatus including the same, according to an aspect of the present disclosure, will be described below.

According to some aspects of the present disclosure, a piezoelectric material composition may comprise a first material, and a second material in the first material. The piezoelectric material composition may be represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M may be strontium (Sr), barium (Ba), or calcium (Ca), E may be the second material, 0.40≤a≤0.60, 0.90≤b≤0.98, 0.30≤c≤0.70, 0.00≤x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T may be antimony (Sb), tantalum (Ta), or vanadium (V), M_{A} may be Sr, Ba, or Ca, M_{B} may be zirconium (Zr), hafnium (Hf), titanium (Ti), or tin (Sn), E may be the second material, 0.40≤a≤0.60, 0.90≤b≤1.00, 0.30≤c≤0.70, 0.00≤x≤0.04, and 0.00<d≤5.00)

According to one or more aspects of the present disclosure, the second material may comprise one or more of NaNbO₃:Eu, BaMgAl₁₀O₁₇:Eu, Y₂O₃:Eu, Y₂SiO₅:Tb, and Zn₂SiO₄:Mn.

According to one or more aspects of the present disclosure, the second material may comprise one or more rare-earth materials.

According to one or more aspects of the present disclosure, the rare-earth material may be configured by 3 mol % or less in a composition of the second material.

According to some aspects of the present disclosure, a piezoelectric device may comprise a piezoelectric device layer including a piezoelectric material composition, a first electrode layer at a first surface of the piezoelectric device layer, and a second electrode layer at a second surface of the piezoelectric device layer different from the first surface. The piezoelectric material composition may comprise a first material, and a second material in the first material, and may be represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M may be strontium (Sr), barium (Ba), or calcium (Ca), E may be the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T may be antimony (Sb), tantalum (Ta), or vanadium (V), M_{A} may be Sr, Ba, or Ca, M_{B} may be zirconium (Zr), hafnium (Hf), titanium (Ti), or tin (Sn), E may be the second material, 0.40≤a≤0.60, 0.90≤b≤1.00, 0.30≤c≤0.70, 0.00≤x≤0.04, and 0.00<d≤5.00.

According to one or more aspects of the present disclosure, the second material may comprise a rare-earth material.

According to one or more aspects of the present disclosure, the second material may comprise one or more of NaNbO₃:Eu, BaMgAl₁₀O₁₇:Eu, Y₂O₃:Eu, Y₂SiO₅:Tb, and Zn₂SiO₄:Mn.

According to one or more aspects of the present disclosure, the second material may comprise a plurality of seeds emitting lights of different colors.

According to one or more aspects of the present disclosure, the second material may comprise a first seed and a second seed each dispersed in the first material. The first seed and the second seed may emit lights of different colors.

According to one or more aspects of the present disclosure, the second material may comprise a first seed, a second seed, and a third seed each dispersed in the first material. The first seed, the second seed, and the third seed may emit lights of different colors.

According to one or more aspects of the present disclosure, each of the first electrode layer and the second electrode layer may include a transparent electrode.

According to one or more aspects of the present disclosure, the transparent electrode may comprise one of indium tin oxide (ITO), PEDOT:PSS, silver nanowire (AgNW), and a metal mesh.

According to some aspects of the present disclosure, a method of manufacturing a piezoelectric device, the method may comprise forming a piezoelectric material composition, forming a first electrode layer at a first surface of the piezoelectric device layer, and forming a second electrode layer at a second surface of the piezoelectric device layer different from the first surface. The piezoelectric material composition may comprise a first material, and a second material in the first material, and may be represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M may be strontium (Sr), barium (Ba), or calcium (Ca), E may be the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T may be antimony (Sb), tantalum (Ta), or vanadium (V), M_{A} may be Sr, Ba, or Ca, M_{B} may be zirconium (Zr), hafnium (Hf), titanium (Ti), or tin (Sn), E may be the second material, 0.40≤a≤0.60, 0.90≤b≤1.00, 0.30≤c≤0.70, 0.00≤x≤0.04, and 0.00<d≤5.00)

According to one or more aspects of the present disclosure, the first material may be a matrix material and may be represented by Equation 3 or 4.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} \qquad Equation 3$$

(M may be Sr, Ba, or Ca, 0.40≤a≤0.60, 0.90≤b≤0.98, 0.30≤c≤0.70, and 0.00<x≤0.04)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} \qquad Equation 4$$

(T may be Sb, Ta, or V, M_{A} may be Sr, Ba, or Ca, M_{B} may be Zr, Hf, Ti, or Sn, 0.40≤a≤0.60, 0.90≤b≤1.00, 0.30≤c≤0.70, and 0.00≤x≤0.04)

According to one or more aspects of the present disclosure, the second material may comprise a rare-earth material.

According to one or more aspects of the present disclosure, each of the first electrode layer and the second electrode layer may include a transparent electrode.

According to one or more aspects of the present disclosure, the forming of the piezoelectric device layer may comprise mixing the first material with the second material to prepare a slurry, molding the slurry to prepare a green tape, and sintering the green tape to prepare a piezoelectric device layer.

According to one or more aspects of the present disclosure, the forming of the piezoelectric device layer may further comprise primarily weighing a raw material of the second material, preparing a secondary seed, secondarily weighing the secondary seed, and preparing a seed.

According to one or more aspects of the present disclosure, the secondary seed may be a BNN seed, and the seed may be an NN seed.

According to some aspects of the present disclosure, an apparatus may comprise a vibration member, and a vibration apparatus configured to vibrate the vibration member. The vibration apparatus may comprise one or more piezoelectric devices. The piezoelectric device may comprise a piezoelectric device layer including a piezoelectric material composition, a first electrode layer at a first surface of the piezoelectric device layer, and a second electrode layer at a second surface of the piezoelectric device layer from the first surface. The piezoelectric material composition may comprise first material, and a second material in the first material, and may be represented by Equation 1 or 2.

$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$

(M may be strontium (Sr), barium (Ba), or calcium (Ca), E may be the second material, 0.40≤a≤0.60, 0.90≤b≤0.98, 0.30≤c≤0.70, 0.00<x≤0.04, and 0.00<d≤5.00)

$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$

(T may be antimony (Sb), tantalum (Ta), or vanadium (V), M_{A} may be Sr, Ba, or Ca, M_{B} may be zirconium (Zr), hafnium (Hf), titanium (Ti), or tin (Sn), E may be the second material, 0.40≤a≤0.60, 0.90≤b≤1.00, 0.30≤c≤0.70, 0.00≤x≤0.04, and 0.00<d≤5.00.

According to one or more aspects of the present disclosure, the vibration member may comprise one or more of a display panel including a plurality of pixels configured to display an image, a screen panel on which an image is to be projected from a display apparatus, a lighting panel, a signage panel, a vehicular interior material, a vehicular glass window, a vehicular exterior material, a ceiling material of a building, an interior material of a building, a glass window of a building, an interior material of an aircraft, and a glass window of an aircraft, or comprises one or more of wood, plastic, glass, metal, cloth, fiber, paper, rubber, leather, carbon, and mirror.

According to one or more aspects of the present disclosure, the vibration apparatus may comprise two or more piezoelectric devices. The two or more piezoelectric devices may be configured to emit lights of different colors along with vibrations.

According to one or more aspects of the present disclosure, the second material may comprise one of Sr₃(PO₄)₅Cl and BaMgAl₁₀O₁₇. Each of the Sr₃(PO₄)₅Cl and the BaMgAl₁₀O₁₇ may have a size of about 10 μm or more.

It will be apparent to those skilled in the art that various modifications and variations may be made in the present disclosure without departing from the scope of the disclosure. Thus, it is intended that the present disclosure covers the modifications and variations of this disclosure provided that within the scope of the claims and their equivalents.

What is claimed is:

1. A piezoelectric material composition comprising:
a first material; and
a second material included in the first material,
wherein the piezoelectric material composition is represented by Equation 1 or 2,
$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$
where M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$
where T is antimony (Sb), tantalum (Ta), or vanadium (V), M_{A} is Sr, Ba, or Ca, M_{B} is zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00.

2. The piezoelectric material composition of claim 1, wherein the second material comprises one or more of NaNbO₃:Eu, BaMgAl₁₀O₁₇:Eu, Y₂O₃:Eu, Y₂SiO₅:Tb, and Zn₂SiO₄:Mn.

3. The piezoelectric material composition of claim 1, wherein the second material comprises one or more rare-earth materials.

4. The piezoelectric material composition of claim 3, wherein the rare-earth material is configured by 3 mol % or less in a composition of the second material.

5. The piezoelectric material composition of claim 1, wherein the second material comprises one of Sr₃(PO₄)₅Cl and BaMgAl₁₀O₁₇, and
wherein each of the Sr₃(PO₄)₅Cl and the BaMgAl₁₀O₁₇ has a size of 10 μm or more.

6. A piezoelectric device, comprising:
a piezoelectric device layer including a piezoelectric material composition;
a first electrode layer disposed at a first surface of the piezoelectric device layer; and
a second electrode layer disposed at a second surface of the piezoelectric device layer different from the first surface, of the piezoelectric device layer,
wherein the piezoelectric material composition comprises a first material, and a second material in the first material, and is represented by Equation 1 or 2,
$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$
where M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$
where T is antimony (Sb), tantalum (Ta), or vanadium (V), M_{A} is Sr, Ba, or Ca, M_{B} is zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00.

7. The piezoelectric device of claim 6, wherein the second material comprises a rare-earth material.

8. The piezoelectric device of claim 7, wherein the rare-earth material is configured by 3 mol % or less in a composition of the second material.

9. The piezoelectric device of claim 6, wherein the second material comprises one or more of NaNbO₃:Eu, BaMgAl₁₀O₁₇:Eu, Y₂O₃:Eu, Y₂SiO₅:Tb, and Zn₂SiO₄:Mn.

10. The piezoelectric device of claim 6, wherein the second material comprises a plurality of seeds emitting lights of different colors.

11. The piezoelectric device of claim 6, wherein the second material comprises a first seed and a second seed each dispersed in the first material, and
wherein the first seed and the second seed emit lights of different colors.

12. The piezoelectric device of claim 6, wherein the second material comprises a first seed, a second seed, and a third seed each dispersed in the first material, and
wherein the first seed, the second seed, and the third seed emit lights of different colors.

13. The piezoelectric device of claim 6, wherein each of the first electrode layer and the second electrode layer includes a transparent electrode.

14. The piezoelectric device of claim 13, wherein the transparent electrode comprises one of indium tin oxide (ITO), PEDOT:PSS, silver nanowire (AgNW), and a metal mesh.

15. The piezoelectric device of claim 6, wherein the second material comprises one of Sr₃(PO₄)₅Cl and BaMgAl₁₀O₁₇, and
wherein each of the Sr₃(PO₄)₅Cl and the BaMgAl₁₀O₁₇ has a size of 10 μm or more.

16. A method of manufacturing a piezoelectric device, the method comprising:
forming a piezoelectric device layer including a piezoelectric material composition;
forming a first electrode layer disposed at a first surface of the piezoelectric device layer; and
forming a second electrode layer disposed at a second surface of the piezoelectric device layer different from the first surface,
wherein the piezoelectric material composition comprises a first material, and a second material in the first material, and is represented by Equation 1 or 2,
$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} + d mol \% E \qquad Equation 1$$
where M is strontium (Sr), barium (Ba), or calcium (Ca), E is the second material, 0.40≤a≤0.60, 0.90≤b≤0.98, 0.30≤c≤0.70, 0.00<x≤0.04, and 0.00<d≤5.00,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} + d mol \% E \qquad Equation 2$$
where T is antimony (Sb), tantalum (Ta), or vanadium (V), M_{A} is Sr, Ba, or Ca, M_{B} is zirconium (Zr), hafnium (Hf), titanium (Ti), or tin (Sn), E is the second material, 0.40≤a≤0.60, 0.90≤b≤1.00, 0.30≤c≤0.70, 0.00≤x≤0.04, and 0.00<d≤5.00.

17. The method of claim 16, wherein the first material is a matrix material and is represented by Equation 3 or 4,
$$0.96 ( {Na}_{a} {K}_{1 - a} ) ( {Nb}_{b} ( {Sb}_{1 - b} ) ) {O}_{3} - ( 0.04 - x ) {M ZrO}_{3} - x ( {Bi}_{c} {Ag}_{1 - c} ) {ZrO}_{3} \qquad Equation 3$$
where M is Sr, Ba, or Ca, 0.40≤a≤0.60, 0.90≤b≤0.98, 0.30≤c≤0.70, and 0.00<x≤0.04,
$$0.96 ( {Na}_{a} {K}_{1 - a} ) ( {Nb}_{b} ( {T}_{1 - b} ) ) {O}_{3} - ( 0.04 - x ) {M}_{A} {M}_{B} {O}_{3} - x ( {Bi}_{c} {Ag}_{1 - c} ) {M}_{B} {O}_{3} \qquad Equation 4$$
where T is Sb, Ta, or V, M_{A} is Sr, Ba, or Ca, M_{B} is Zr, Hf, Ti, or Sn, 0.40≤a≤0.60, 0.90≤b≤1.00, 0.30≤c≤0.70, and 0.00≤x≤0.04.

18. The method of claim 16, wherein the second material comprises a rare-earth material.

19. The method of claim 18, wherein the rare-earth material is configured by 3 mol % or less in a composition of the second material.

20. The method of claim 16, wherein each of the first electrode layer and the second electrode layer includes a transparent electrode.

21. The method of claim 16, wherein the forming of the piezoelectric device layer comprises:
mixing the first material with the second material to prepare a slurry;
molding the slurry to prepare a green tape; and
sintering the green tape to prepare a piezoelectric device layer.

22. The method of claim 21, further comprising:
primarily weighing a raw material of the second material;
preparing a secondary seed;
secondarily weighing the secondary seed; and
preparing a seed.

23. The method of claim 22, wherein the secondary seed is a BNN seed, and the seed is an NN seed.

24. The method of claim 16, wherein the second material comprises one or more of NaNbO₃:Eu, BaMgAl₁₀O₁₇:Eu, Y₂O₃:Eu, Y₂SiO₅:Tb, and Zn₂SiO₄:Mn.

25. The method of claim 16, wherein the second material comprises one of Sr₃(PO₄)₅Cl and BaMgAl₁₀O₁₇, and
wherein each of the Sr₃(PO₄)₅Cl and the BaMgAl₁₀O₁₇ has a size of 10 μm or more.

26. An apparatus, comprising:
a vibration member; and
a vibration apparatus configured to vibrate the vibration member,
wherein the vibration apparatus comprises one or more piezoelectric devices of claim 1.

27. The apparatus of claim 26, wherein the vibration member comprises one or more of a display panel including a plurality of pixels configured to display an image, a screen panel on which an image is to be projected from a display apparatus, a lighting panel, a signage panel, a vehicular interior material, a vehicular glass window, a vehicular exterior material, a ceiling material of a building, an interior material of a building, a glass window of a building, an interior material of an aircraft, and a glass window of an aircraft, or comprises one or more of wood, plastic, glass, metal, cloth, fiber, paper, rubber, leather, carbon, and mirror.

28. The apparatus of claim 26, wherein the vibration apparatus comprises two or more piezoelectric devices, and
wherein the two or more piezoelectric devices are configured to emit lights of different colors along with vibrations.
